(19) United States
(12) Patent Application Publication
(10) Pub. No.: US 2024/0355866 A1
(43) Pub. Date: Oct. 24, 2024

(54) PHOTOELECTRIC CONVERSION APPARATUS AND EQUIPMENT

(71) Applicant: CANON KABUSHIKI KAISHA, Tokyo (JP)

(72) Inventors: KOJI HARA, Chiba (JP); ALICE EHARA, Kanagawa (JP); HIROSHI SEKINE, Kanagawa (JP)

(21) Appl. No.: 18/626,478

(22) Filed: Apr. 4, 2024

(30) Foreign Application Priority Data
Apr. 18, 2023 (JP) 2023-068087

(51) Int. Cl. H01L 27/146

(52) U.S. Cl. CPC H01L 27/14643; H01L 27/14607; H01L 27/14636; H01L 27/14634

(57) ABSTRACT

A photoelectric conversion apparatus includes a semiconductor substrate having an avalanche diode. The avalanche diode has a first semiconductor region of a first conductivity type that is disposed at a first depth from a first surface of the semiconductor substrate, and a second semiconductor region of a second conductivity type that is disposed at a second depth that is deeper than the first depth from the first surface, and a first negative fixed charge film in contact with the first surface is formed.

### BACKGROUND OF THE INVENTION

### Field of the Invention

The technique of the present disclosure relates to a photoelectric conversion apparatus and an equipment.

### Description of the Related Art

In a photoelectric conversion apparatus, there is a technique of improving a quantum conversion efficiency by increasing the optical path length of incident light in a photoelectric conversion element in the apparatus by providing a reflection plate that reflects the incident light. Also, US Patent Application Publication No. 2020/0286946 proposes a single-photon avalanche diode (SPAD) having anode wiring extending in one direction with respect to a substrate. Furthermore, US Patent Application Publication No. 2019/0181177 proposes an SPAD having anode wiring extending in all directions with respect to a substrate.

However, the structure of the SPAD described in US Patent Application Publication No. 2020/0286946 is problematic in that cathode wiring is present directly above a guard ring region, and therefore hot carriers are trapped near the cathode region, whereby the potential changes and the breakdown voltage changes over time.

Also, the structure of the SPAD described in the specification of US Patent Application Publication No. 2019/0181177 is problematic in that the distance between the anode wiring and the cathode wiring is short, resulting in a decrease in the withstand voltage.

The technique of the present disclosure has been made in view of the above problems, and aims to provide a technique that solves problems related to the withstand voltage and reduces change in the breakdown voltage over time.

### SUMMARY OF THE INVENTION

According to some embodiments, a photoelectric conversion apparatus includes a semiconductor substrate having an avalanche diode, wherein the avalanche diode has a first semiconductor region of a first conductivity type that is disposed at a first depth from a first surface of the semiconductor substrate, and a second semiconductor region of a second conductivity type that is disposed at a second depth that is deeper than the first depth from the first surface, and a first negative fixed charge film in contact with the first surface is formed.

According to some embodiments, an equipment including the photoelectric conversion as described above includes at least any of: an optical device corresponding to the photoelectric conversion apparatus; a control device configured to control the photoelectric conversion apparatus; a processing device configured to process a signal output from the photoelectric conversion apparatus; a display device configured to display information obtained by the photoelectric conversion apparatus; a storage device configured to store information obtained by the photoelectric conversion apparatus; and a machine device configured to operate based on information obtained by the photoelectric conversion apparatus.

Further features of the present invention will become apparent from the following description of exemplary embodiments with reference to the attached drawings.

### BRIEF DESCRIPTION OF THE DRAWINGS

FIG. 1 is a schematic diagram of a photoelectric conversion apparatus according to an embodiment;

FIG. 2 is a schematic diagram of a semiconductor substrate of a photoelectric conversion apparatus according to an embodiment;

FIG. 3 is a schematic diagram of a circuit board of a photoelectric conversion apparatus according to an embodiment;

FIG. 4 is a configuration example of a pixel circuit of a photoelectric conversion apparatus according to an embodiment;

FIGS. 5A and 5B are schematic diagrams showing driving of a pixel circuit of a photoelectric conversion apparatus according to an embodiment;

FIG. 6 is a plan view of a photoelectric conversion apparatus according to a first embodiment;

FIG. 7 is a cross-sectional view of the photoelectric conversion apparatus according to the first embodiment;

FIG. 8 is a plan view of a photoelectric conversion apparatus according to Variation 1 of the first embodiment;

FIG. 9 is a cross-sectional view of the photoelectric conversion apparatus according to Variation 1 of the first embodiment;

FIG. 10 is a plan view of a photoelectric conversion apparatus according to Variation 2 of the first embodiment;

FIG. 11 is a cross-sectional view of the photoelectric conversion apparatus according to Variation 2 of the first embodiment;

FIG. 12 is a plan view of a photoelectric conversion apparatus according to Variation 3 of the first embodiment;

FIG. 13 is a cross-sectional view of the photoelectric conversion apparatus according to Variation 3 of the first embodiment;

FIG. 14 is a plan view of a photoelectric conversion apparatus according to Variation 4 of the first embodiment;

FIG. 15 is a cross-sectional view of the photoelectric conversion apparatus according to Variation 4 of the first embodiment;

FIG. 16 is a plan view of a photoelectric conversion apparatus according to Variation 5 of the first embodiment;

FIG. 17 is a cross-sectional view of a photoelectric conversion apparatus according to Variation 5 of the first embodiment;

FIG. 18 is a cross-sectional view of a photoelectric conversion apparatus according to a second embodiment; and

FIG. 19 is a schematic diagram of an equipment including a photoelectric conversion apparatus according to a third embodiment.

### DESCRIPTION OF THE EMBODIMENTS

Hereinafter, embodiments of the present disclosure will be described in detail with reference to the drawings. Note that in the following description, terms indicating specific directions and positions (e.g., “up”, “down”, “right”, “left”, and other terms including these terms) are used as necessary. These terms are used to facilitate understanding of the embodiments with reference to the drawings, and the technical scope of the present disclosure is not limited by the meanings of these terms. Also, these terms are used to embody the technical idea of the present disclosure, and do not limit the present disclosure. Constituent elements of each embodiment can be added to other embodiments or replaced with constituent elements of other embodiments. Also, the sizes and positional relationships of members shown in each drawing are exaggerated for clarity of description in some cases.

Also, in the following description, “plan view” refers to viewing from a direction perpendicular to a light incident surface of a semiconductor layer. Also, “cross-sectional view” refers to a plane in a direction perpendicular to the light incident surface of the semiconductor layer. Note that when the light incident surface of the semiconductor layer is a rough surface when viewed microscopically, a plan view is defined based on the light incident surface of the semiconductor layer when viewed macroscopically.

Also, in the photoelectric conversion apparatus described in each embodiment below, an anode of an avalanche photodiode (APD) is set to a fixed potential, and a signal is extracted from the cathode side. Accordingly, a semiconductor region of a first conductivity type whose majority carriers are charges of the same polarity as the signal charge is an N-type semiconductor region, and a semiconductor region of a second conductivity type whose majority carriers are charges of a polarity different from the signal charge is a P-type semiconductor region.

Note that the following embodiments can also be applied to a case where the cathode of the APD is set at a fixed potential and a signal is extracted from the anode side. In this case, the semiconductor region of the first conductivity type whose majority carriers are charges of the same polarity as the signal charge is a P-type semiconductor region, and the semiconductor region of the second conductivity type whose majority carriers are charges of a polarity different from the signal charge is an N-type semiconductor region. Although a case will be described below in which one node of the APD has a fixed potential, the potentials of both nodes may vary.

Furthermore, in the following description, when the term “impurity concentration” is simply used, it means the net impurity concentration after subtracting the amount compensated for by impurities of the opposite conductivity type. That is, “impurity concentration” refers to the net doping concentration. A region where the P-type added impurity concentration is higher than the N-type added impurity concentration is a P-type semiconductor region. On the other hand, a region where the N-type added impurity concentration is higher than the P-type added impurity concentration is an N-type semiconductor region.

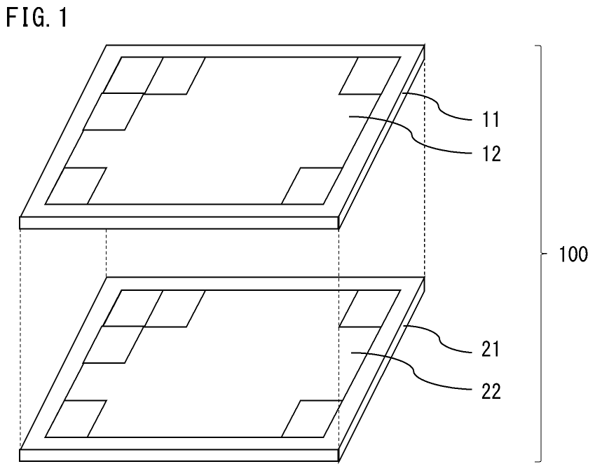

First, configurations common to each embodiment of a photoelectric conversion apparatus and driving method therefor will be described with reference to FIG. 1 to FIGS. 5A and 5B.

FIG. 1 is a diagram showing the configuration of a stacked photoelectric conversion apparatus 100 according to each embodiment. In the photoelectric conversion apparatus 100, a sensor substrate 11 on which a pixel region 12 is disposed and a circuit board 21 on which a circuit region 22 is disposed are stacked, and the sensor substrate 11 and the circuit board 21 are electrically connected to each other. The sensor substrate 11 includes a first semiconductor layer having later-described photoelectric conversion elements 102, and a first wiring structure. The circuit board 21 includes a second semiconductor layer having circuits such as later-described signal processing units 103, and a second wiring structure. In the photoelectric conversion apparatus 100, the second semiconductor layer, the second wiring structure, the first wiring structure, and the first semiconductor layer are stacked in the stated order. The photoelectric conversion apparatus 100 is a back-illuminated photoelectric conversion apparatus in which a circuit board is disposed on a first surface (front surface) and light from a light source is incident from a second surface (back surface).

In the following description, it is assumed that the sensor substrate 11 and the circuit board 21 are diced chips, but the sensor substrate 11 and the circuit board 21 are not limited to chips. For example, the sensor substrate 11 and the circuit board 21 may also be wafers. Also, the sensor substrate 11 and the circuit board 21 may be formed by stacking them in a wafer state and then dicing them, or by forming them into chips and then stacking and bonding the chips. The pixel region 12 is disposed on the sensor substrate 11, and the circuit region 22 for processing a signal detected in the pixel region 12 is arranged on the circuit board 21.

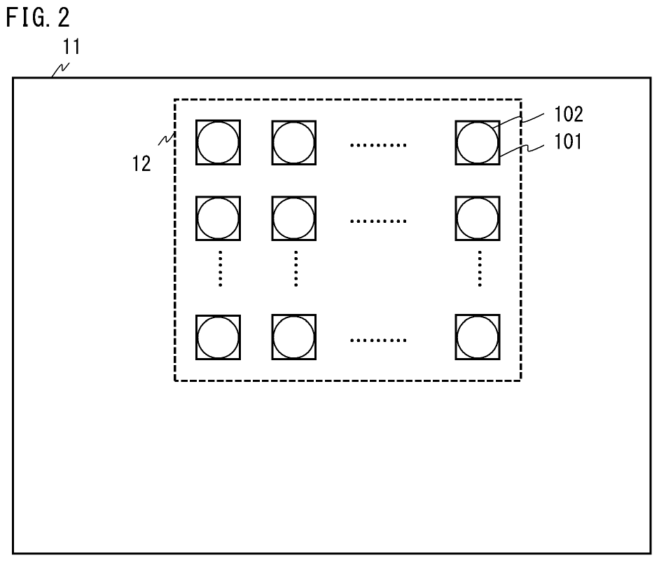

FIG. 2 is a diagram showing an example of the arrangement of the sensor substrate 11. In the sensor substrate 11, the pixel region 12 is formed by arranging pixels 101 having photoelectric conversion elements 102 including avalanche photodiodes (hereinafter referred to as APDs), in a two-dimensional array in a plan view. The pixels 101 are typically pixels for forming an image, but when used for TOF (Time of Flight), the pixels 101 do not necessarily need to form an image. That is, the pixels 101 may also be pixels for measuring the time when light arrives and the amount of light.

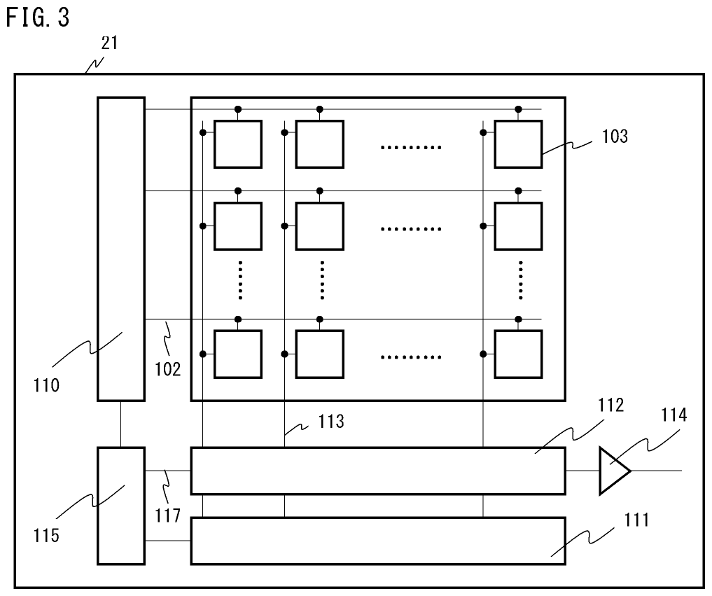

FIG. 3 is a schematic configuration diagram schematically showing the configuration of the circuit board 21. The circuit board 21 includes signal processing units 103 that process charges photoelectrically converted by the photoelectric conversion elements 102 in FIG. 2, a column circuit 112, a control pulse generation unit 115, a horizontal scanning circuit portion 111, a signal line 113, and a vertical scanning circuit portion 110. Also, the photoelectric conversion elements 102 in FIG. 2 and the signal processing units 103 in FIG. 3 are electrically connected to each other via connection wiring provided for each pixel.

The vertical scanning circuit portion 110 receives the control pulse supplied from the control pulse generation unit 115, and supplies the control pulse to each pixel. The vertical scanning circuit portion 110 uses logic circuits such as shift registers and address decoders. The signals output from the photoelectric conversion elements 102 are processed by the signal processing units 103. The signal processing units 103 each include a counter, a memory, and the like, and the memory of the signal processing unit 103 holds digital values related to processing performed by the signal processing unit 103.

The horizontal scanning circuit portion 111 inputs a control pulse for sequentially selecting each column to the signal processing unit 103 in order to read out a digital signal from the memory of each pixel in which the digital signal is held. Then, for the selected column, the digital signal from the signal processing unit 103 of the pixel selected by the vertical scanning circuit portion 110 is output to the signal line 113. The digital signal output to the signal line 113 is output to a recording unit or a signal processing unit outside the photoelectric conversion apparatus 100 via the output circuit 114.

In FIG. 2, the photoelectric conversion elements in the pixel region may also be arranged one-dimensionally. Also, since the effect of each embodiment can be obtained even with one pixel, each embodiment can be applied to a configuration with one pixel. Also, the function of the signal processing unit 103 does not necessarily need to be provided in all photoelectric conversion elements, and for example, a configuration may also be used in which a plurality of photoelectric conversion elements share one signal processing unit and the signal processing unit sequentially performs signal processing for each photoelectric conversion element.

As shown in FIGS. 2 and 3, a plurality of signal processing units 103 are disposed in a region overlapping with the pixel region 12 in a plan view. Also, in a plan view, the vertical scanning circuit portion 110, the horizontal scanning circuit portion 111, the column circuit 112, the output circuit 114, and the control pulse generation unit 115 are disposed so as to overlap with the gap between the edge of the sensor substrate 11 and the edge of the pixel region 12. That is, the sensor substrate 11 has the pixel region 12 and a non-pixel region disposed around the pixel region 12. The vertical scanning circuit portion 110, the horizontal scanning circuit portion 111, the column circuit 112, the output circuit 114, and the control pulse generation unit 115 are disposed in a region overlapping with the non-pixel region in a plan view.

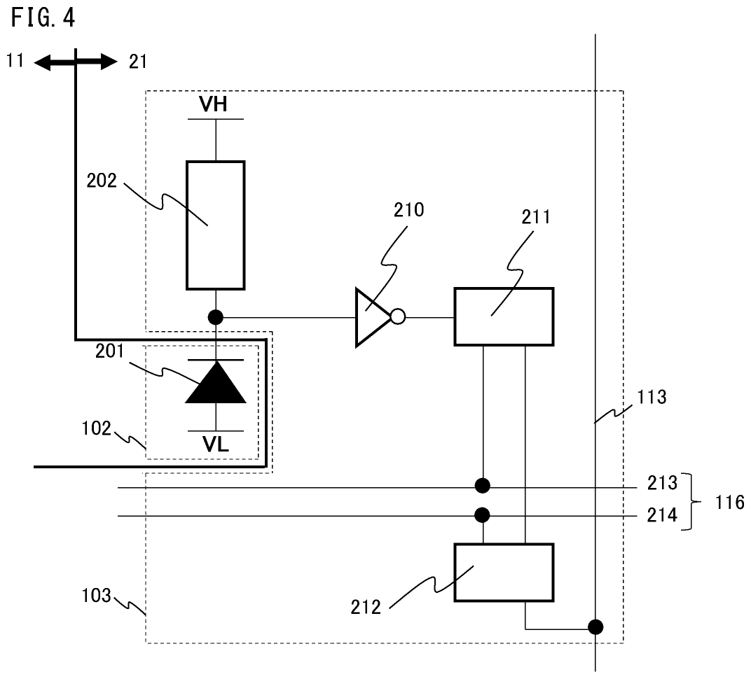

FIG. 4 is an example of a block diagram including the equivalent circuit of FIGS. 2 and 3. As shown in FIG. 4, the photoelectric conversion element 102 has an APD 201, the photoelectric conversion element 102 is provided on the sensor substrate 11, and the other constituent elements are provided on the circuit board 21.

The APD 201 generates charge pairs according to incident light through photoelectric conversion. The anode of the APD 201 is supplied with a voltage VL (first voltage). Also, the cathode of the APD 201 is supplied with a voltage VH (second voltage) that is higher than the voltage VL supplied to the anode. A reverse bias voltage that causes avalanche multiplication in the APD 201 is supplied to the anode and the cathode. In the APD 201, when such a voltage is supplied, avalanche multiplication is caused by charges generated by incident light, whereby an avalanche current is generated.

Note that the APD 201 operates in a Geiger mode in which the APD 201 is operated with a potential difference between the anode and the cathode that is greater than the breakdown voltage when a reverse bias voltage is supplied. Also, the APD 201 operates in a linear mode in which the APD 201 is operated with a potential difference between the anode and the cathode that is close to or below the breakdown voltage when a reverse bias voltage is supplied.

An APD that operates in the Geiger mode is called a single-photon avalanche diodes (SPAD). For example, the voltage VL (first voltage) can be −30 V, and the voltage VH (second voltage) can be 1 V. Note that the APD 201 may also be operated in the linear mode or the Geiger mode. In the case of a SPAD, the potential difference is larger than that of an APD in the linear mode and the effect of the withstand voltage is significant, and therefore it is preferable that the APD 201 operates as a SPAD.

A quench element 202 is connected to the APD 201 and a power source that supplies the voltage VH. The quench element 202 functions as a load circuit (quench circuit) during signal multiplication through avalanche multiplication, and has a function of suppressing the voltage supplied to the APD 201 and suppressing avalanche multiplication (quench operation). Also, the quench element 202 plays the role of returning the voltage supplied to the APD 201 to the voltage VH by allowing a current equivalent to the amount by which the voltage has dropped due to the quench operation to flow (recharge operation).

The signal processing unit 103 includes a waveform shaping unit 210, a counter circuit 211, and a selection circuit 212. Note that the signal processing unit 103 need only be configured to include any one of the waveform shaping unit 210, the counter circuit 211, and the selection circuit 212.

The waveform shaping unit 210 shapes the potential change at the cathode of the APD 201 obtained during photon detection and outputs a pulse signal. As the waveform shaping unit 210, for example, an inverter circuit is used. Although FIG. 4 shows an example in which one inverter is used as the waveform shaping unit 210, a circuit in which multiple inverters are connected in series may be used as the waveform shaping unit 210, or other circuits that have a waveform shaping effect may be used as the waveform shaping unit 210.

The counter circuit 211 counts the pulse signals output from the waveform shaping unit 210 and holds a value indicating the count number. Also, when a control pulse pRES is supplied to the counter circuit 211 through a drive line 213, the signal held in the counter circuit 211 is reset.

The selection circuit 212 is supplied with a control pulse pSEL from the vertical scanning circuit portion 110 in FIG. 3 through a drive line 214 (not shown in FIG. 3) in FIG. 4, and the counter circuit 211 and the signal line 113 can be switched between electrical connection and disconnection by the selection circuit 212. The selection circuit 212 includes, for example, a buffer circuit for outputting a signal.

By disposing a switch such as a transistor between the quench element 202 and the APD 201 or between the photoelectric conversion element 102 and the signal processing unit 103, the electrical connection state of these constituent elements may be switched. Similarly, the supply of the voltage VH or the voltage VL supplied to photoelectric conversion element 102 may be electrically switched using a switch such as a transistor.

The example shown in FIG. 4 shows a configuration using the counter circuit 211. However, it is also possible to form a photoelectric conversion apparatus 100 that acquires the pulse detection timing using a time-to-digital converter (hereinafter referred to as a TDC) and a memory, instead of the counter circuit 211. In this case, the generation timing of the pulse signal output from the waveform shaping unit 210 is converted into a digital signal by the TDC. In measuring the timing of the pulse signal, a control pulse pREF (reference signal) is supplied to the TDC from the vertical scanning circuit portion 110 in FIG. 1 through a drive line. The TDC acquires, as a digital signal, a signal obtained when the input timing of the signal output from each pixel via the waveform shaping unit 210 is set as a relative time using the control pulse pREF as a reference.

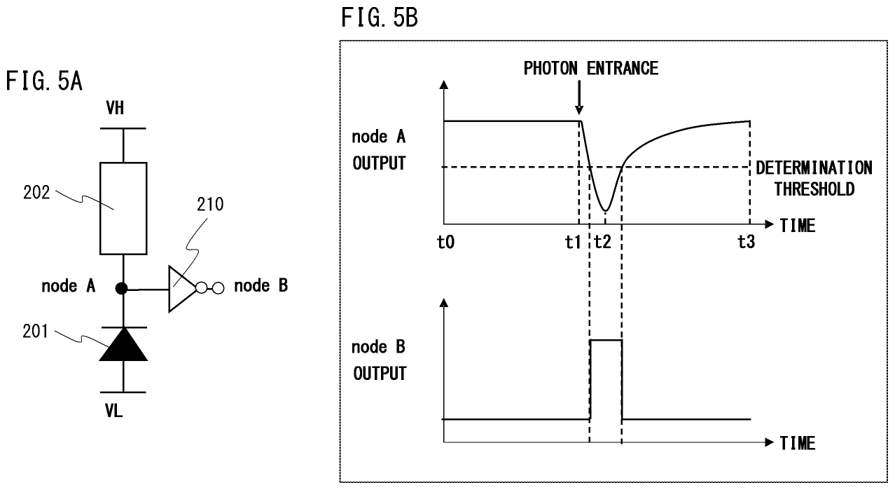

FIGS. 5A and 5B are diagrams schematically showing the relationship between the operation of the APD 201 and the output signal. FIG. 5A shows the APD 201, the quench element 202, and the waveform shaping unit 210 of FIG. 4. Here, the input side of the waveform shaping unit 210 is node A, and the output side is node B. FIG. 5B shows a waveform change of node A in FIG. 5A and a waveform change of node B in FIG. 5A.

As shown in FIG. 5B, a potential difference of VH-VL is applied to the APD 201 in FIG. 5A between time t0 and time t1. At time t1, when a photon enters the APD 201, avalanche multiplication occurs in the APD 201, an avalanche multiplication current flows through the quench element 202, and the voltage at node A drops. When the amount of voltage drop further increases and the potential difference applied to the APD 201 becomes smaller, avalanche multiplication of APD 201 stops as at time t2, and the voltage level of node A no longer drops beyond a certain value. Thereafter, between time t2 and time t3, a current that compensates for the voltage drop from the voltage VL flows through the node A, and at time t3, the node A is statically fixed at the original potential level. At this time, the portion of the output waveform at the node A that exceeds a certain threshold is waveform-shaped by the waveform shaping unit 210 and output as a signal at the node B.

Note that the arrangement of the signal line 113, the column circuit 112, and the output circuit 114 is not limited to the arrangement shown in FIG. 3. For example, the signal line 113 may be disposed extending in the row direction, and the column circuit 112 may be connected to the end of the signal line 113.

Hereinafter, a photoelectric conversion apparatus according to each embodiment will be described.

### First Embodiment

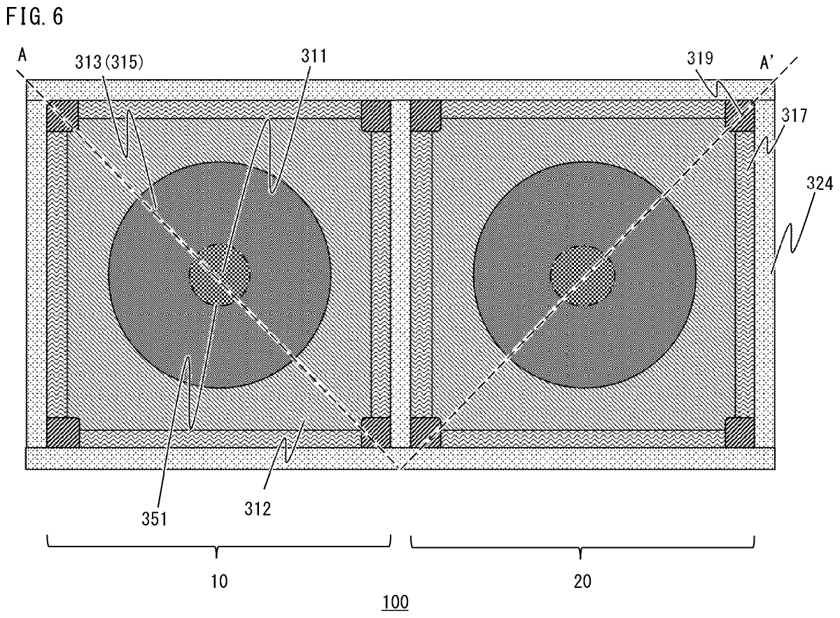

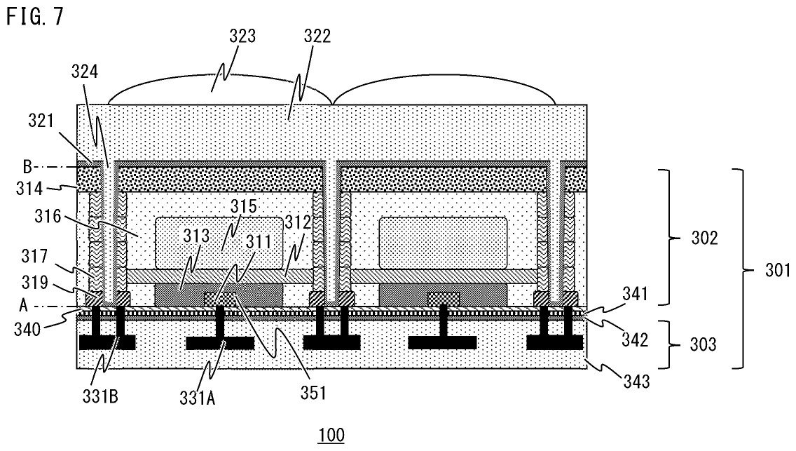

A photoelectric conversion apparatus according to the first embodiment will be described with reference to FIGS. 6 and 7. FIG. 6 is a plan view of two pixels of the photoelectric conversion apparatus 100 according to the present embodiment, and is a plan view of the pixels when viewed from a surface opposite to the light incident surface of the pixels. Also, FIG. 7 is a cross-sectional view of two pixels in a direction perpendicular to the substrate of the photoelectric conversion apparatus 100 according to the present embodiment, and corresponds to a cross section taken along line A-A′ in FIG. 6. Note that, for convenience of description, the plan view of the photoelectric conversion apparatus 100 in FIG. 6 also shows portions as transparent in order to show the positional relationship of each part.

In this embodiment, as an example, it is assumed that the photoelectric conversion apparatus 100 is an avalanche multiplication type photoelectric conversion apparatus. First, the structure and function of the photoelectric conversion apparatus 100 will be described. As shown in FIG. 6, the photoelectric conversion apparatus 100 includes an avalanche photodiode (APD) 10, which is a first photoelectric conversion element constituting one pixel, and an avalanche photodiode (APD) 20, which is a second photoelectric conversion element constituting another pixel. Also, as shown in FIG. 7, the photoelectric conversion apparatus 100 includes a semiconductor substrate 301 including a semiconductor layer 302 and a wiring layer 303.

The semiconductor layer 302 is, for example, a semiconductor layer that is an N-type semiconductor region. The semiconductor layer 302 is made of silicon, for example. The semiconductor layer 302 has a first surface (the surface indicated by “A” in the drawings) and a second surface (the surface indicated by “B” in the drawings) opposite to the first surface. The first surface A and the second surface B of the semiconductor layer 302 are the front surface and the back surface of the semiconductor layer 302, respectively, and serve as boundary surfaces with other members. Also, the first surface A side is the side on which the wiring layer 303 is disposed, and the second surface B side is the side on which light from the light source is incident.

First, the structure and function of the photoelectric conversion element 102 will be described. As shown in FIG. 7, the photoelectric conversion element 102 includes a first semiconductor region 311, a third semiconductor region 313, a fifth semiconductor region 315, and a sixth semiconductor region 316, which are N-type. Also, the photoelectric conversion element 102 includes a second semiconductor region 312, a fourth semiconductor region 314, a seventh semiconductor region 317, and a ninth semiconductor region 319, which are P-type.

In this embodiment, as shown in FIG. 7, in the semiconductor layer 302, the N-type first semiconductor region 311 is formed on the first surface A side, which is the surface opposite to the light incident surface on which light from the light source enters. Also, the N-type third semiconductor region 313 that covers at least a portion of the first semiconductor region 311 is formed around the first semiconductor region 311. Also, in a plan view of the semiconductor substrate 301, the P-type second semiconductor region 312 is formed at a position overlapping with the first semiconductor region 311 and the third semiconductor region 313. Also, in a plan view of the semiconductor substrate 301, the N-type fifth semiconductor region 315 is formed at a position overlapping with the second semiconductor region 312, and the N-type sixth semiconductor region 316 is formed around the fifth semiconductor region 315. Also, the second semiconductor region 312 and the third semiconductor region 313 are formed such that, in a plan view, the area of the second semiconductor region 312 is smaller than the area obtained by subtracting the area of the second semiconductor region 312 from the area of the third semiconductor region 313. As a result, in the photoelectric conversion apparatus 100, the effect of reducing the change in breakdown voltage over time can be expected.

The N-type impurity concentration of the first semiconductor region 311 is higher than the N-type impurity concentration of the third semiconductor region 313 and the fifth semiconductor region 315. Also, a PN junction is formed between the P-type second semiconductor region 312 and the N-type first semiconductor region 311. By making the impurity concentration of the second semiconductor region 312 lower than the impurity concentration of the first semiconductor region 311, a region of the second semiconductor region 312 that overlaps with the first semiconductor region 311 in a plan view becomes a depletion layer region. At this time, the potential difference between the first semiconductor region 311 and the second semiconductor region 312 becomes larger than the potential difference between the second semiconductor region 312 and the fifth semiconductor region 315. Furthermore, this depletion layer region extends to a partial region of the first semiconductor region 311, and a strong electric field is induced in the extended depletion layer region. This strong electric field causes avalanche multiplication in the depletion layer region extending to a partial region of the first semiconductor region 311, and a current based on the amplified charges is output as a signal charge.

Light incident on the APDs 10 and 20 from the second surface B side is photoelectrically converted, and when avalanche multiplication occurs in the above-described depletion layer region (avalanche multiplication region), generated charges of the first conductivity type gather in the first semiconductor region 311. Note that in FIG. 6, the third semiconductor region 313 and the fifth semiconductor region 315 are formed to have the same size in a plan view, but the size of each semiconductor region is not limited to this. For example, by forming the fifth semiconductor region 315 larger than the third semiconductor region 313 in a plan view, charges can be collected in the first semiconductor region 311 from a wider range.

Also, the two APDs 10 and 20 are isolated by an isolation portion 324 having a trench structure. The P-type seventh semiconductor region 317 formed around the isolation portion 324 isolates the APDs 10 and 20 by a potential barrier. The APDs 10 and 20 are also isolated by the potential of the seventh semiconductor region 317. Accordingly, a trench structure such as the isolation portion 324 is not essential as an isolation portion for a photoelectric conversion element, and even when the isolation portion 324 having a trench structure is provided, its depth and position are not limited to the configuration shown in FIG. 6. The isolation portion 324 may also be a DTI (deep trench isolation) that penetrates through the semiconductor layer, or may be a DTI that does not penetrate through the semiconductor layer. Also, the isolation portion 324 may be configured to surround the entire periphery of the APD 10 and/or the APD 20 in a plan view. Alternatively, in a plan view, the isolation portion 324 may be configured to surround at least a part of the APD 10 and/or the APD 20, and for example, in a plan view, the isolation portion 324 may be formed in a rectangular shape and two isolation portions 324 may be disposed at positions sandwiching the APD 10.

On the first surface A side of the semiconductor layer 302 opposite to the light incident surface (second surface B), a wiring layer 303 having a wiring structure including a conductor and an insulating film is provided. The APDs 10 and 20 include, starting from the side closer to the semiconductor layer 302, a first fixed charge film 340 that is in contact with the first surface A, an oxide film 341, and a protective film 342. Also, a wiring interlayer film 343 is provided on the protective film 342. The protective film 342 is formed on the fixed charge film to protect the avalanche diode from plasma damage and metal contamination during etching. For the protective film 342, SiN, which is a nitride film, is generally used, but SION, SiC, SiCN, or the like may also be used.

Here, the first fixed charge film 340 is a film having a negative fixed charge, and is preferably made of, for example, a metal compound film. More preferably, the first fixed charge film 340 is made of hafnium oxide, zirconium oxide, aluminum oxide, titanium oxide, or tantalum oxide, and is particularly preferably made of aluminum oxide. A film containing these metal compounds as a main component may also be used.

Here, the effect obtained by the photoelectric conversion apparatus 100 according to this embodiment will be described. Hot carriers generated by the strong electric field around the first semiconductor region 311 are repelled by the negative fixed charges of the first fixed charge film 340 disposed between the first surface A of the semiconductor substrate 301 and the oxide film 341. This makes it difficult for hot carriers to be trapped, for example, at the interface between the oxide film 341 and the protective film 342, at the interface level of the first surface A of the semiconductor substrate 301, or the like. In particular, there is growing concern that when hot carriers are trapped at the interface between the oxide film 341 and the protective film 342 near the boundary portion 351, the potential distribution in the avalanche region in the semiconductor layer 302 will be affected and the breakdown voltage will change. Accordingly, by disposing the first fixed charge film 340 having a negative fixed charge, trapping of hot carriers generated at the interface portion near the charge detection units of the APDs 10 and 20 can be reduced, and it is possible to expect a reduction of change in the breakdown voltage over time.

In the photoelectric conversion apparatus according to the above-described conventional technique, there is concern that the withstand voltage will decrease due to the short distance between the anode wiring and the cathode wiring. On the other hand, according to the photoelectric conversion apparatus 100 according to the present embodiment, the distance between the cathode wiring 331A, which is the first wiring portion, and the anode wiring 331B, which is the second wiring portion, can be made longer than in the case of the conventional technique, and therefore there is no concern that the withstand voltage will decrease, which is a concern in the conventional art. As described above, in the photoelectric conversion apparatus 100 according to the present embodiment, by providing the first fixed charge film 340 while maintaining a sufficient distance between the cathode wiring 331A and the anode wiring 331B, it is possible to achieve a high withstand voltage and reduce change over time in the breakdown voltage.

Also, in the photoelectric conversion apparatus 100, a second fixed charge film 321, a flattening film 322, and a microlens 323 are further disposed on the second surface B side, which is the light incident surface of the semiconductor layer 302. Note that a filter layer or the like may also be further arranged on the second surface B side of the semiconductor layer 302. Various optical filters such as color filters, infrared light cut filters, and monochrome filters can be used for this filter layer. Also, as the color filter, an RGB color filter, an RGBW color filter, or the like can be used.

Here, the first fixed charge film 340 and the second fixed charge film 321 are formed such that the charge density of the first fixed charge film 340 is smaller than the charge density of the second fixed charge film 321. Also, the second fixed charge film 321 is a film having a negative fixed charge, and is preferably made of, for example, a metal compound film. More preferably, the second fixed charge film 321 is made of hafnium oxide, zirconium oxide, aluminum oxide, titanium oxide, or tantalum oxide, and is particularly preferably made of aluminum oxide. A film containing these metal compounds as a main component may also be used. Also, the first fixed charge film 340 and the second fixed charge film 321 may have the same composition or may have different compositions. For example, both the first fixed charge film 340 and the second fixed charge film 321 can be made of aluminum oxide to obtain a composition film having a large negative fixed charge. As a result, trapping of hot carriers on the first surface A side of the semiconductor layer 302 and a dark count rate (DCR) on the second surface B of the semiconductor layer 302 can be further suppressed.

Also, for example, the first fixed charge film 340 can be made of hafnium oxide and the second fixed charge film 321 can be made of aluminum oxide. In this way, by disposing a composition film with a large negative fixed charge, the DCR on the second surface B side of the semiconductor layer 302 can be suppressed, and on the first surface A, it is possible to suppress the cathode wiring 331A and the anode wiring 331B from being electrically connected via the interface of the first fixed charge film 340. As a result, the occurrence of trapping of hot carriers in the photoelectric conversion apparatus 100 can be reduced.

Also, for example, in the cross section of the photoelectric conversion apparatus 100 in FIG. 7, the thickness of the first fixed charge film 340 is made larger than the thickness of the second fixed charge film 321. As a result, the DCR on the second surface B side of the semiconductor layer 302 can be further suppressed by the pinning performance, which is inversely correlated with the film thickness. Furthermore, on the first surface A side of the semiconductor layer 302, the effect of suppressing electrical connection between the cathode wiring and the anode wiring through the interface of the fixed charge film and reducing the occurrence of carrier traps can also be expected.

### Variation 1

A plurality of variations (Variations 1 to 5) of the first embodiment will be described below. Note that in the following description of the variations, the same components as in the first embodiment are denoted by the same reference numerals, and detailed description thereof is omitted.

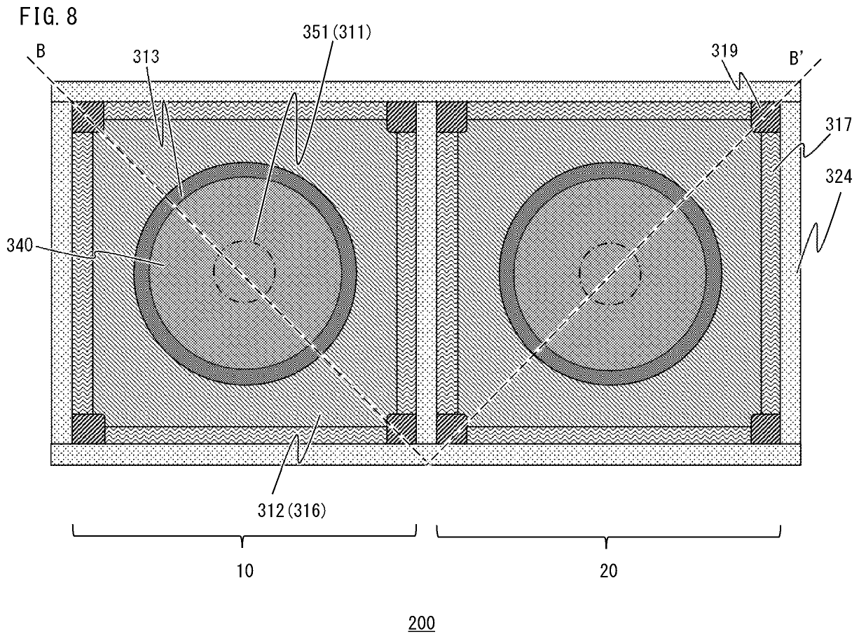

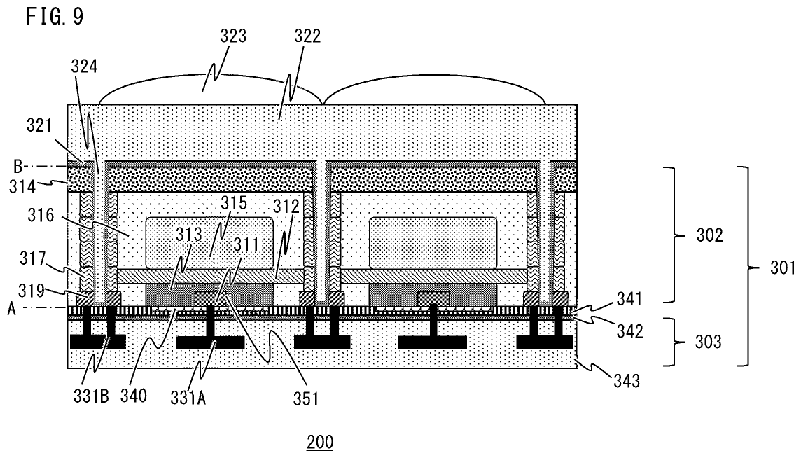

FIGS. 8 and 9 show a photoelectric conversion apparatus 200 according to Variation 1. FIG. 8 is a plan view of two pixels of the photoelectric conversion apparatus 200 according to this variation, and is a plan view of the pixels when viewed from the surface opposite to the light incident surface of the pixels. Note that, for convenience of description, the plan view of the photoelectric conversion apparatus 200 in FIG. 8 also shows portions as transparent in order to show the positional relationship of each part. Also, FIG. 9 is a cross-sectional view of two pixels in the direction perpendicular to the substrate of the photoelectric conversion apparatus 200 according to the present variation, and corresponds to a cross section taken along line B-B′ in FIG. 8.

As shown in FIG. 8, in the photoelectric conversion apparatus 200, the first fixed charge film 340 is disposed so as to cover at least a boundary portion 351, which is a portion where the first semiconductor region 311 and the third semiconductor region 313 are in contact with each other, in a plan view. Also, the first fixed charge film 340 is disposed within a region formed by the first semiconductor region 311 and the third semiconductor region 313, so as to overlap with part of the third semiconductor region 313 in a plan view. Furthermore, in a plan view, the first fixed charge film 340 is disposed so as not to be in contact with the sixth semiconductor region 316. As a result, the first fixed charge film 340 is disposed so as to cover the region where the anode wiring 331B is not present in a plan view.

With this arrangement of the first fixed charge film 340, in the photoelectric conversion apparatus 200, it is possible to suppress electrical connection between the cathode wiring 331A and the anode wiring 331B through the interface of the first fixed charge film 340. Also, in the photoelectric conversion apparatus 200, trapping of hot carriers can be reduced in regions where carrier traps have a greater influence on change in the breakdown voltage over time.

### Variation 2

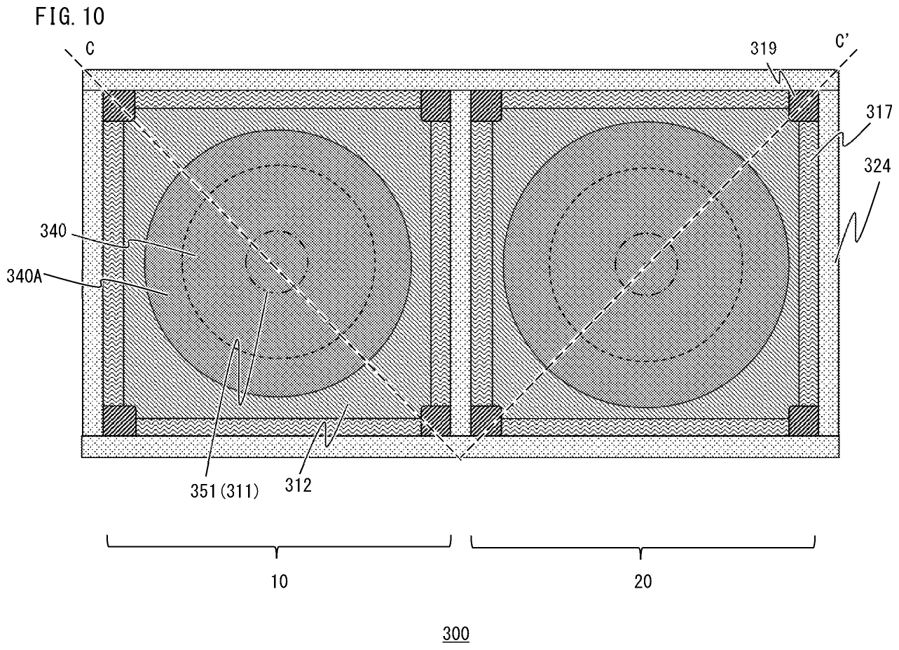

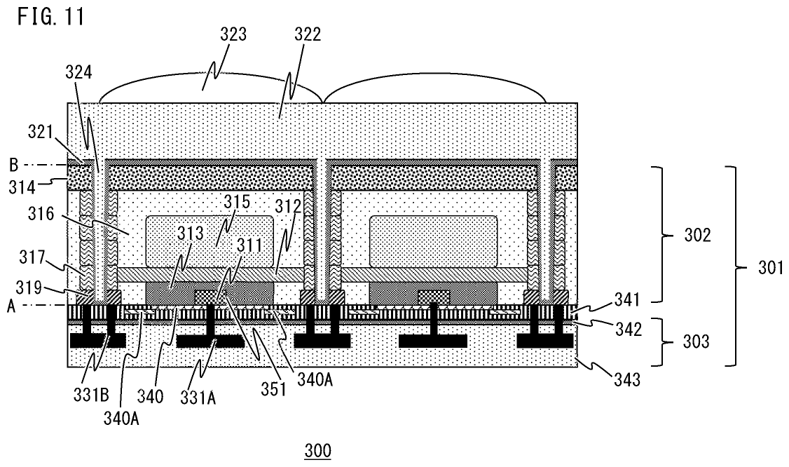

Next, FIGS. 10 and 11 show a photoelectric conversion apparatus 300 according to Variation 2. FIG. 10 is a plan view of two pixels of the photoelectric conversion apparatus 300 according to this variation, and is a plan view of the pixels when viewed from the surface opposite to the light incident surface of the pixels. Note that, for convenience of description, the plan view of the photoelectric conversion apparatus 300 in FIG. 10 also shows portions as transparent in order to show the positional relationship of each part. Also, FIG. 11 is a cross-sectional view of two pixels in a direction perpendicular to the substrate of the photoelectric conversion apparatus 300 according to this variation, and corresponds to a cross section taken along line C-C′ in FIG. 10.

In the cross section shown in FIG. 11, in the photoelectric conversion apparatus 300, end portions 340A of a first fixed charge film 340 are disposed so as not to be in contact with the first surface A of the semiconductor layer 302. An oxide film 341 is disposed between the first fixed charge film 340, which is the end portion region of the first fixed charge film 340, and the first surface A. With this arrangement of the first fixed charge film 340, the photoelectric conversion apparatus 300 can prevent the semiconductor layer 302 from being damaged by etching when the first fixed charge film 340 is etched. Also, in the photoelectric conversion apparatus 300, the occurrence of trapping of hot carriers can be reduced without deteriorating the DCR.

Also, as shown in FIG. 11, in the photoelectric conversion apparatus 300, a protective film 342 is stacked on a flattened oxide film 341. As a result, in the vicinity of the boundary portion 351 between the first semiconductor region 311 and the third semiconductor region 313, the protective film 342 is disposed spaced apart from the first surface A of the semiconductor layer 302 by an amount corresponding to the thickness of the first fixed charge film 340 and the oxide film 341. As a result, in the photoelectric conversion apparatus 300, the phenomenon in which hot carriers are trapped in the protective film 342 can be further suppressed, and the DCR can be suppressed by the protective film 342.

### Variation 3

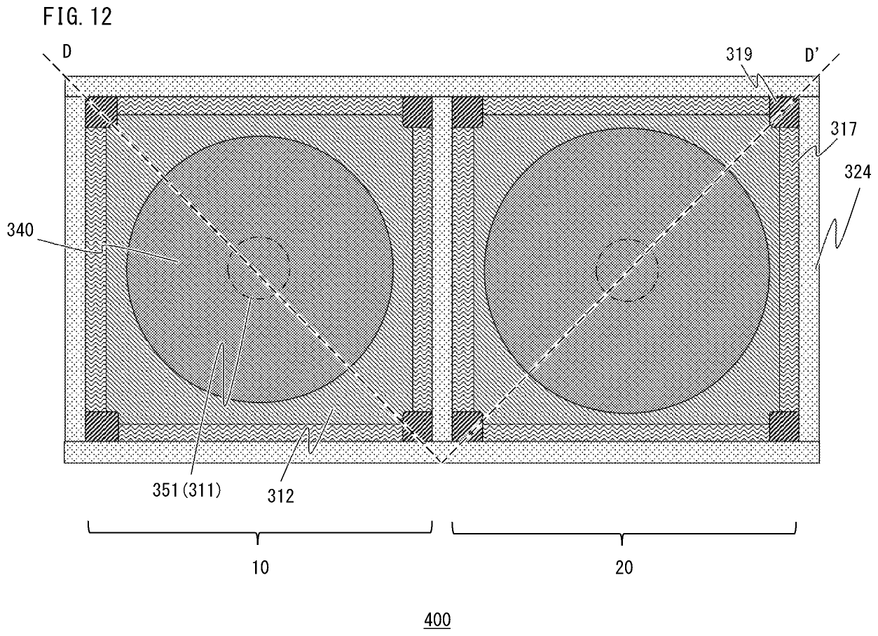

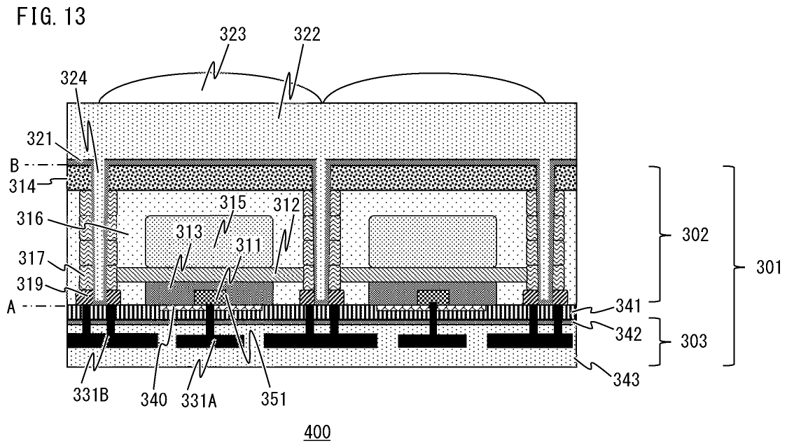

Next, FIGS. 12 and 13 show a photoelectric conversion apparatus 400 according to Variation 3. FIG. 12 is a plan view of two pixels of the photoelectric conversion apparatus 400 according to this variation, and is a plan view of the pixels when viewed from the surface opposite to the light incident surface of the pixels. Note that, for convenience of description, the plan view of the photoelectric conversion apparatus 400 in FIG. 12 also shows portions as transparent in order to show the positional relationship of each part. Also, FIG. 13 is a cross-sectional view of two pixels in a direction perpendicular to the substrate of the photoelectric conversion apparatus 400 according to this variation, and corresponds to a cross section taken along line D-D′ in FIG. 12.

As shown in FIG. 13, in the photoelectric conversion apparatus 400, the anode wiring 331B is extended farther toward the cathode wiring 331A compared to the photoelectric conversion apparatus 100, 200, and 300. The length of the anode wiring 331B extending toward the cathode wiring 331A, that is, the distance between the anode wiring 331B and the cathode wiring 331A, can be determined as appropriate within a range where there is little concern about the withstand voltage. In a plan view, when comparing the area of the cathode wiring 331A and the area of the anode wiring 331B in the same wiring layer 303 where the cathode wiring 331A and the anode wiring 331B are disposed, the area of the cathode wiring 331A is smaller than the area of the anode wiring 331B. In the photoelectric conversion apparatus 400 of this embodiment, the cathode wiring 331A and the anode wiring 331B are configured in this manner, and therefore pinning performance can be obtained and changes in breakdown voltage over time can be suppressed.

Also, in a plan view, the first fixed charge film 340 is disposed so as not to be in contact with the anode wiring 331B. As a result, in the photoelectric conversion apparatus 400, the first fixed charge film 340 can generate a repulsive force on the carriers in a region where the repulsive force caused by the anode wiring 331B does not reach the carriers. As a result, in the photoelectric conversion apparatus 400, it is possible to suppress a change in breakdown voltage over time while suppressing trapping of hot carriers.

### Variation 4

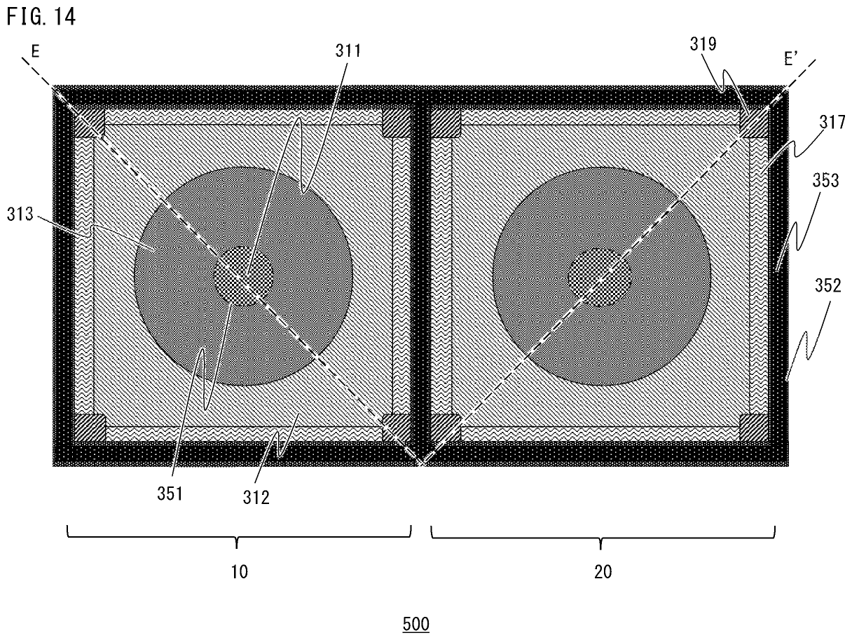

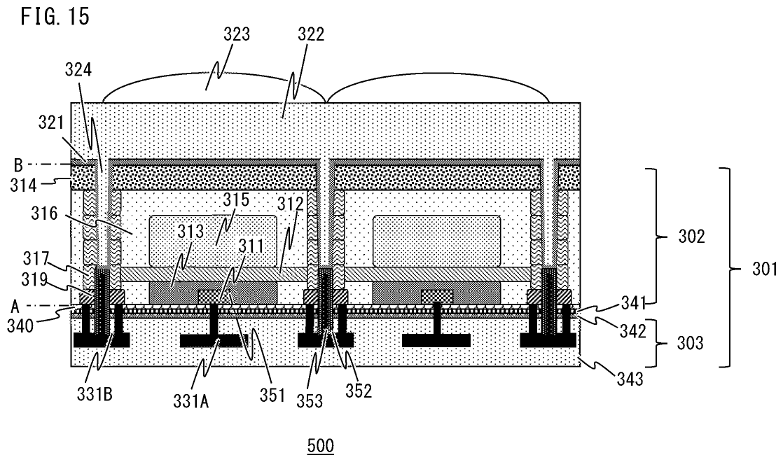

Next, FIGS. 14 and 15 show a photoelectric conversion apparatus 500 according to Variation 4. FIG. 14 is a plan view of two pixels of a photoelectric conversion apparatus 500 according to this variation, and is a plan view of the pixels when viewed from the surface opposite to the light incident surface of the pixels. Note that, for convenience of description, the plan view of the photoelectric conversion apparatus 500 in FIG. 14 also shows portions as transparent in order to show the positional relationship of each part. Also, FIG. 15 is a cross-sectional view of two pixels in a direction perpendicular to the substrate of the photoelectric conversion apparatus 500 according to this variation, and corresponds to a cross section taken along line E-E′ in FIG. 14.

As shown in FIG. 15, the photoelectric conversion apparatus 500 is provided with an isolation portion 324 that isolates the APDs 10 and 20. The isolation portion 324 is formed by embedding conductive material 353 within the DTI. By applying a voltage to the embedded conductive material 353 in the isolation portion 324, charges are induced at the trench interface and the DCR is suppressed.

Also, in the isolation portion 324, a third fixed charge film 352 is embedded together with the conductive material 353. Here, the third fixed charge film 352 is a film having a negative fixed charge, and is preferably made of, for example, a metal compound film. More preferably, the third fixed charge film 352 is made of hafnium oxide, zirconium oxide, aluminum oxide, titanium oxide, or tantalum oxide, and is particularly preferably made of aluminum oxide. A film containing these metal compounds as a main component may also be used.

The first fixed charge film 340, the second fixed charge film 321, and the third fixed charge film 352 may also have the same composition or may have different compositions. For example, the first fixed charge film 340, the second fixed charge film 321, and the third fixed charge film 352 can all be made of aluminum oxide to obtain composition films with large negative fixed charges. As a result, trapping of hot carriers on the first surface A of the semiconductor layer 302 and the DCR of the isolation portion 324 on the second surface B of the semiconductor layer 302 can be further suppressed.

Also, for example, the first fixed charge film 340 can be made of hafnium oxide, and the second fixed charge film 321 and the third fixed charge film 352 can be made of aluminum oxide. In this manner, by disposing a composition film with a large negative fixed charge, the DCR on the second surface B side of the semiconductor layer 302 can be suppressed, and on the first surface A, it is possible to suppress the cathode wiring 331A and the anode wiring 331B from being electrically connected to each other via the interface of the first fixed charge film 340. As a result, the occurrence of trapping of hot carriers in the photoelectric conversion apparatus 500 can be reduced.

Also, for example, the first fixed charge film 340 can be made of hafnium oxide, the second fixed charge film 321 can be made of aluminum oxide, and the third fixed charge film 352 can be made of titanium oxide. In this case, by disposing a composition film with a large negative fixed charge on the second surface B of the semiconductor layer 302 and disposing a composition film with a small negative fixed charge on the isolation portion 324, the DCR on the second surface B side can be suppressed and the DCR of the isolation portion 324 can be suppressed by applying a voltage to the conductive material 353. As a result, in the photoelectric conversion apparatus 500, the first surface A of the semiconductor layer 302 can prevent electrical connection between the cathode wiring 331A and the anode wiring 331B through the interface of the first fixed charge film 340, and can reduce the occurrence of trapping of hot carriers.

### Variation 5

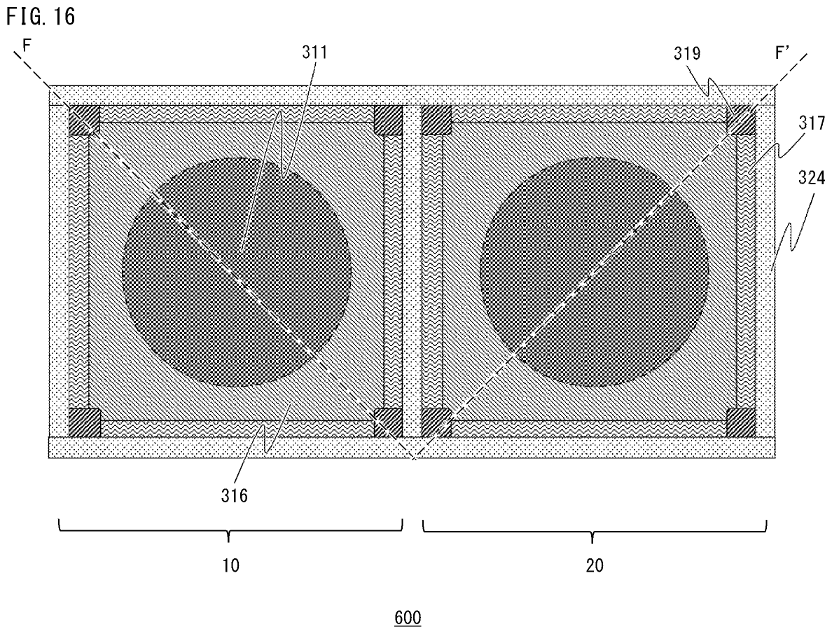

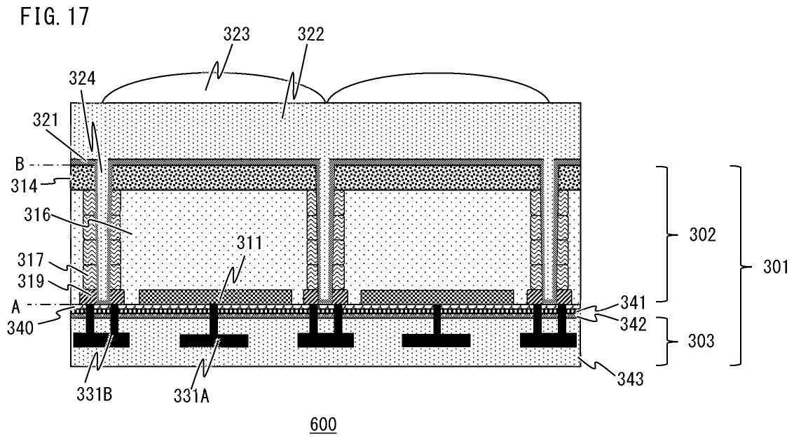

Next, FIGS. 16 and 17 show a photoelectric conversion apparatus 600 according to Variation 5. FIG. 16 is a plan view of two pixels of the photoelectric conversion apparatus 600 according to this variation, and is a plan view of the pixels when viewed from the surface opposite to the light incident surface of the pixels. Note that, for convenience of description, the plan view of the photoelectric conversion apparatus 600 in FIG. 16 also shows portions as transparent in order to show the positional relationship of each part. Also, FIG. 17 is a cross-sectional view of two pixels in a direction perpendicular to the substrate of the photoelectric conversion apparatus 600 according to this variation, and corresponds to a cross section taken along line F-F′ in FIG. 16.

As shown in FIGS. 16 and 17, in the photoelectric conversion apparatus 600, the semiconductor regions in the APDs 10 and 20 include, for example, the first semiconductor region 311 and the sixth semiconductor region 316. In the photoelectric conversion apparatus 600 having the APDs 10 and 20 configured in this manner as well, the first fixed charge film 340 can generate a repulsive force against the carriers, reduce the occurrence of trapping of hot carriers, and suppress change in the breakdown voltage over time.

### Second Embodiment

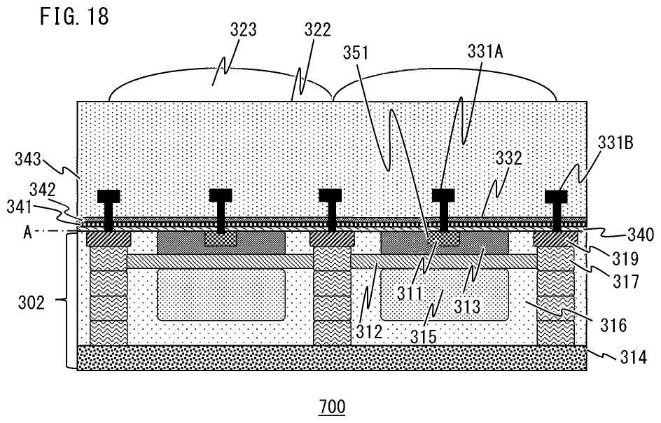

Next, a photoelectric conversion apparatus according to a second embodiment will be described. Note that in the following description, the same components as in the first embodiment are denoted by the same reference numerals, and detailed description is omitted. FIG. 18 shows a photoelectric conversion apparatus 700 according to this embodiment. FIG. 18 is a cross-sectional view of two pixels in the direction perpendicular to the substrate of the photoelectric conversion apparatus 700, and corresponds to a cross section taken along line A-A′ in FIG. 7 in the first embodiment.

As shown in FIG. 18, the photoelectric conversion apparatus 700 is a front-side-illuminated photoelectric conversion apparatus, cathode wiring 331A and anode wiring 331B are disposed on a first surface A side of a semiconductor layer 302, and light from a light source enters the APDs 10 and 20 from the first surface A side. Also, as shown in FIG. 18, a first fixed charge film 340 is stacked on the first surface A of the semiconductor layer 302 to prevent reflection of incident light. Here, the stacked structure of the first fixed charge film 340 is not limited to the illustrated structure, and for example, a metal oxide film or the like may be further stacked on the first fixed charge film 340, or a configuration without the protective film 342 may be used. Also, similarly to the first embodiment, the first fixed charge film 340 may be disposed only in a partial region of the first surface A in a plan view. Also, similarly to the first embodiment, the arrangement of the first fixed charge film 340 may be changed depending on the region of the first surface A in order to prevent reflection of incident light.

According to the photoelectric conversion apparatus 700 of to the present embodiment, in a front-side-illuminated photoelectric conversion apparatus as well, it is possible to reduce the occurrence of trapping of hot carriers and there is no concern that the sensitivity of the APD will be reduced.

### Third Embodiment

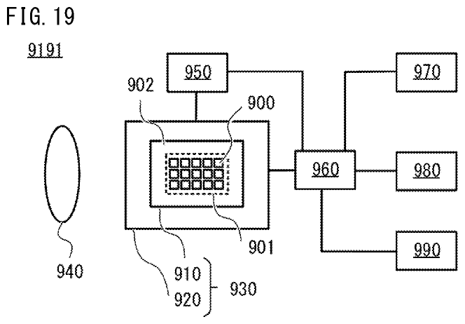

Any of the first and second embodiments described above can be applied to a third embodiment. FIG. 19 is a schematic view for describing equipment 9191 including a semiconductor apparatus 930 of the present embodiment. The semiconductor apparatus 930 can be any of the photoelectric conversion apparatuses described in the first and second embodiments, or a photoelectric conversion apparatus obtained by combining these embodiments. The equipment 9191 including the semiconductor apparatus 930 will be described in detail. The semiconductor apparatus 930 can include a semiconductor device 910 having a semiconductor layer, and a package 920 which houses the semiconductor device 910. The package 920 can include a substrate to which the semiconductor device 910 is fixed, and a lid made of glass or the like which faces the semiconductor device 910. The package 920 can further include a joining member such as a bonding wire or a bump which connects a terminal provided on the substrate and a terminal provided on the semiconductor device 910.

The equipment 9191 can include at least any of an optical device 940, a control device 950, a processing device 960, a display device 970, a storage device 980, and a mechanical device 990. The optical device 940 is compliant with the semiconductor apparatus 930. The optical device 940 is, e.g., a lens, a shutter, or a mirror. The control device 950 controls the semiconductor apparatus 930. The control device 950 is a semiconductor apparatus such as, e.g., an ASIC.

The processing device 960 processes a signal output from the semiconductor apparatus 930. The processing device 960 is a semiconductor apparatus such as a CPU or an ASIC for constituting an AFE (analog front end) or a DFE (digital front end). The display device 970 is an EL display device or a liquid crystal display device which displays information (image) obtained by the semiconductor apparatus 930. The storage device 980 is a magnetic device or a semiconductor device which stores information (image) obtained by the semiconductor apparatus 930. The storage device 980 is a volatile memory such as an SRAM or a DRAM, or a non-volatile memory such as a flash memory or a hard disk drive.

The mechanical device 990 has a moving unit or a propulsive unit such as a motor or an engine. In the equipment 9191, a signal output from the semiconductor apparatus 930 is displayed in the display device 970, and is transmitted to the outside by a communication device (not shown) provided in the equipment 9191. In order to do so, it is preferable that the equipment 9191 further includes the storage device 980 and the processing device 960 in addition to a storage circuit and an operation circuit of the semiconductor apparatus 930. The mechanical device 990 may also be controlled on the basis of a signal output from the semiconductor apparatus 930.

In addition, the equipment 9191 is suitably used as electronic equipment such as an information terminal having photographing function (e.g., a smartphone or a wearable terminal) or a camera (e.g., an interchangeable-lens camera, a compact camera, a video camera, or a surveillance camera). The mechanical device 990 in the camera can drive components of the optical device 940 for zooming, focusing, and shutter operation. Alternatively, the mechanical device 990 in the camera can move the semiconductor apparatus 930 for vibration isolation operation.

The equipment 9191 can be transport equipment such as a vehicle, a ship, or a flight vehicle. The mechanical device 990 in the transport equipment can be used as a moving device. The equipment 9191 serving as the transport equipment is suitably used as equipment which transports the semiconductor apparatus 930, or performs assistance and/or automation of driving (manipulation) with photographing function. The processing device 960 for assistance and/or automation of driving (manipulation) can perform processing for operating the mechanical device 990 serving as the moving device based on information obtained in the semiconductor apparatus 930. Alternatively, the equipment 9191 may also be medical equipment such as an endoscope, measurement equipment such as a distance measurement sensor, analysis equipment such as an electron microscope, office equipment such as a copier, or industrial equipment such as a robot.

According to the third embodiment as described above, it becomes possible to obtain excellent pixel characteristics. Consequently, it is possible to enhance the value of the semiconductor apparatus 930. At least any of addition of function, an improvement in performance, an improvement in characteristics, an improvement in reliability, an improvement in product yield, a reduction in environmental load, a reduction in cost, a reduction in size, and a reduction in weight corresponds to the enhancement of the value thereof mentioned herein.

Consequently, if the semiconductor apparatus 930 according to the third embodiment is used in the equipment 9191, it is possible to improve the value of the equipment as well. For example, when the semiconductor apparatus 930 is mounted on transport equipment and photographing of the outside of the transport equipment or measurement of an external environment is performed, it is possible to obtain excellent performance. Therefore, when the transport equipment is manufactured and sold, it is advantageous to determine that the semiconductor apparatus 930 according to the third embodiment is mounted on the transport equipment in terms of increasing the performance of the transport equipment itself. The semiconductor apparatus 930 is suitably used particularly as the transport equipment which performs driving assistance and/or automated driving of the transport equipment by using information obtained by the semiconductor apparatus 930.

Respective embodiments described up to this point, can be appropriately changed within the scope not departing from the technical idea. Incidentally, the contents disclosed in the present specification includes not only the description in the present specification but also all the matters comprehensible from the present specification and the drawings appended in the present specification. Further, the disclosed contents of the present specification include the complement of the concept described in the present specification. Namely, it can be said as follows: a description in the present specification to the effect that “A is larger than B” discloses to the effect that “A is not larger than B” even when the description to the effect that “A is not larger than B” is omitted. This is because it is a premise that the case where there is a description to the effect that “A is larger than B” is accomplished in consideration of the case where “A is not larger than B”.

According to the technique of the present disclosure, problems related to breakdown voltage can be solved and changes in the withstand voltage over time can be reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-068087, filed on Apr. 18, 2023, which is hereby incorporated by reference herein in its entirety.

What is claimed is:

1. A photoelectric conversion apparatus, comprising:
a semiconductor substrate having an avalanche diode, wherein
the avalanche diode has a first semiconductor region of a first conductivity type that is disposed at a first depth from a first surface of the semiconductor substrate, and a second semiconductor region of a second conductivity type that is disposed at a second depth that is deeper than the first depth from the first surface, and
a first negative fixed charge film in contact with the first surface is formed.

2. The photoelectric conversion apparatus according to claim 1, wherein in the semiconductor substrate, the first surface is a surface on an opposite side to a light incident surface for light that is incident on the avalanche diode.

3. The photoelectric conversion apparatus according to claim 1, wherein a protective film is formed on the first negative fixed charge film.

4. The photoelectric conversion apparatus according to claim 1, wherein the avalanche diode further includes a third semiconductor region of the first conductivity type, which covers at least part of the first semiconductor region.

5. The photoelectric conversion apparatus according to claim 4, wherein in a plan view, an area of the second semiconductor region is smaller than an area obtained by subtracting the area of the second semiconductor region from an area of the third semiconductor region.

6. The photoelectric conversion apparatus according to claim 1, wherein in a plan view, the first semiconductor region is disposed in a region where the first negative fixed charge film is disposed.

7. The photoelectric conversion apparatus according to claim 1, wherein in a plan view, the first semiconductor region is disposed in a region where the second semiconductor region is disposed.

8. The photoelectric conversion apparatus according to claim 1, wherein
a first wiring portion electrically connected to the first semiconductor region and a second wiring portion electrically connected to the second semiconductor region are disposed in a wiring layer of the semiconductor substrate, and
in a plan view, an area of the first wiring portion in the wiring layer is smaller than an area of the second wiring portion in the wiring layer.

9. The photoelectric conversion apparatus according to claim 4, wherein in a plan view, the first negative fixed charge film covers at least a portion where the first semiconductor region and the third semiconductor region are in contact with each other.

10. The photoelectric conversion apparatus according to claim 4, wherein in a plan view, the first negative fixed charge film is disposed within a region formed by the first semiconductor region and the third semiconductor region.

11. The photoelectric conversion apparatus according to claim 8, wherein in a plan view, the first negative fixed charge film is disposed so as to cover a region where the second wiring portion is not present.

12. The photoelectric conversion apparatus according to claim 8, wherein in a plan view, the first negative fixed charge film is disposed so as not to be in contact with the second wiring portion.

13. The photoelectric conversion apparatus according to claim 2, wherein a second negative fixed charge film is formed on the light incident surface.

14. The photoelectric conversion apparatus according to claim 13, wherein a charge concentration of the first negative fixed charge film is smaller than a charge concentration of the second negative fixed charge film.

15. The photoelectric conversion apparatus according to claim 13, wherein a thickness of the first negative fixed charge film is larger than a thickness of the second negative fixed charge film.

16. The photoelectric conversion apparatus according to claim 1, wherein the first negative fixed charge film contains a metal oxide.

17. The photoelectric conversion apparatus according to claim 1, wherein the first negative fixed charge film contains hafnium oxide, zirconium oxide, aluminum oxide, titanium oxide, or tantalum oxide.

18. The photoelectric conversion apparatus according to claim 13, wherein the first negative fixed charge film and the second negative fixed charge film contain hafnium oxide, zirconium oxide, aluminum oxide, titanium oxide, or tantalum oxide.

19. The photoelectric conversion apparatus according to claim 13, wherein the first negative fixed charge film and the second negative fixed charge film contain aluminum oxide.

20. The photoelectric conversion apparatus according to claim 13, wherein the first negative fixed charge film is made of hafnium oxide, and the second negative fixed charge film contains aluminum oxide.

21. The photoelectric conversion apparatus according to claim 1, wherein an oxide film is disposed between the first surface an end portion region of the first negative fixed charge film.

22. The photoelectric conversion apparatus according to claim 8, wherein
an isolation portion, which is made of a conductive material and which isolates the avalanche diode and another avalanche diode from each other, is disposed on the semiconductor substrate, and
the isolation portion is connected to the second wiring portion.

23. An equipment including the photoelectric conversion apparatus according to claim 1, the equipment further comprising at least any of:
an optical device corresponding to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus; and
a machine device configured to operate based on information obtained by the photoelectric conversion apparatus.
